(19) United States
(12) Patent Application Publication
(10) Pub. No.: US 2009/0184638 A1
(43) Pub. Date: Jul. 23, 2009

(54) FIELD EMITTER IMAGE SENSOR DEVICES, SYSTEMS, AND METHODS

(75) Inventor: Thomas W. Voshell, Boise, ID (US)

Correspondence Address: TRASK BRITT, P.C./ MICRON TECHNOLOGY, P.O. BOX 2550, SALT LAKE CITY, UT, 84110, US

(73) Assignee: Micron Technology, Inc., Boise, ID (US)

(21) Appl. No.: 12/017,689

(22) Filed: Jan. 22, 2008

(51) Int. Cl. H01J 40/16; H01L 27/00

(52) U.S. Cl. 313/531; 250/208.1

(57) ABSTRACT

Methods, devices, and systems for a field emitter image sensor device are disclosed. A field emitter image sensor device includes a substrate operably coupled to a ground voltage. The substrate includes a first surface configured for sensing light incident thereto and a second surface comprising a plurality of emitter tips configured to emit electrons. The field emitter image sensor device further includes a plurality of anodes opposite the plurality of emitter tips and configured to receive the emitted electron charges. Furthers the field emitter image sensor device comprises a plurality of charge integrators configured to output the electron charges on the anodes to a pixel array, wherein each charge integrator is operably coupled to one anode of the plurality.

### TECHNICAL FIELD

Embodiments of the invention relate generally to an imaging device and, more specifically, to an image sensor device comprising a plurality of field emitter tips and a pixel array.

### BACKGROUND OF THE INVENTION

Field emission displays (“FEDs”) and image sensor devices are well known in the art of imaging. FEDs, using field emitters, may be implemented in a variety of devices, such as portable computers and other lightweight, portable information display devices. Image sensor devices may be used in a variety of imaging applications including medical products, navigational equipment, and consumer products such as digital cameras and cellular phones.

Conventional FEDs use electron emissions to illuminate a cathodoluminescent screen and generate a visual image. An individual field emission cell typically includes one or more emitter sites formed on a baseplate. The baseplate typically contains the active semiconductor devices that control electron emissions from the emitter sites. A gate electrode structure, or grid, is typically associated with the emitter sites. The emitter sites and grid are connected to an electrical source for establishing a voltage differential to cause a Fowler-Nordheim electron emission from the emitter sites. These electrons strike a display screen having a phosphor coating. This excitation of the phosphor releases the photons that illuminate the screen. A single pixel of the display screen is typically illuminated by one or several emitter sites.

FIG. 1 illustrates a pixel site 110 of a conventional FED 100 and portions of adjacent pixel sites 111 on either side. The FED 100 includes a baseplate 104 having a substrate 112 and a plurality of emitter tips 114 formed on the substrate 112. When a voltage differential, generated by a voltage source 128, is applied between emitter tips 114 and the cathodoluminescent display screen 118, electrons 120 are emitted from the emitter tips 114. These electrons 120 strike the phosphor material coating 122 on the cathodoluminescent display screen 118. The electrons striking the phosphor material coating 122 produces the photons (not shown) that illuminate the cathodoluminescent display screen 118 and generate a visual image. Conventional FEDs, as described above, may have longevity concerns due to the tendency of the phosphorus coating 122 to decay over time.

An image sensor device is a semiconductor device with the capacity to convert an optical image into an electrical signal. Many systems include image sensor devices to sense and capture optical images that can be electronically converted to a digital representation of the image. Image sensor devices include an array of photo-sensitive devices such as photodiodes or photo-transistors fabricated on, for example, a complementary metal oxide semiconductor (CMOS) substrate. Each photosensitive device is sensitive to light in such a way that it can create an electrical charge that is proportional to the intensity of light striking the photo-sensitive device. The overall image captured by an image sensor device includes many pixels arranged in an array such that each pixel detects the light intensity at the location of that pixel.

Image sensor devices fabricated according to a conventional Complementary Metal Oxide Semiconductor (CMOS) process are known as CMOS imagers and may be configured to include active pixel sensors (APS). An active pixel sensor (APS) includes an integrated circuit containing an array of pixels, each containing a photo detector (e.g., photodiode or other similar device) as well as other transistors for resetting and gating the stored charge on the photo detectors. In a conventional CMOS imager, each pixel cell in an array of pixels operates to convert light intensity to electrical charge, accumulate the electrical charge in proportion to the light intensity, and transfer the accumulated charge to an amplifier. In many CMOS imagers, a pixel may be reset to a specific reference voltage level prior to, or after, acquiring the image.

FIG. 2A is a circuit representation of a pixel 200 within a conventional image sensor device. A photodiode PD configured for collecting a charge generated thereto may be operably coupled to the source of a transfer transistor M_{T} configured for transferring the charge to an operably coupled floating diffusion region FD. Floating diffusion region FD is configured for passing a charge to the gate of operably coupled source-follower transistor M_{SF}. In addition, floating diffusion region FD may be operably coupled to the drain of a reset transistor M_{RST}, which is configured to reset the floating diffusion region FD to a predetermined voltage before a charge is transferred thereto from photodiode PD. The source of reset transistor M_{RST} may be operably coupled to source supply voltage Vaa which may also be operably coupled to source-follower transistor M_{SF}. Reset transistor M_{RST} may be controlled by a reset signal RST which may be asserted to turn on reset transistor M_{RST} and, as a result, reset the voltage at the floating diffusion region FD to a supply voltage Vaa. The gate of transfer transistor M_{T} may be operably coupled to a transfer signal TX which may be asserted to turn on the transfer transistor M_{T} and allow a charge to be transferred from photodiode PD to floating diffusion region FD. Subsequently, ROW ENABLE may be asserted to turn on row select transistor M_{SEL}, and allow current to flow tough source-follower transistor M_{SF} and row select transistor M_{SEL} and onto column line output 210 that is proportional to the charge on the gate of source-follower transistor M_{SF}.

FIG. 21 illustrates a cross-sectional view of a portion of a pixel array 250 comprising two adjacent pixels P1 and P2 within a conventional image sensor device. Pixels P1 and P2 each comprise a photodiode PD within a charge collection region 252 operably coupled to a transfer transistor M_{T} and configured for collecting charge generated by light incident on the pixel. The drain of each transfer transistor M_{T} is operably coupled to a floating diffusion region FD, which is, in turn, operably coupled to a drain of a reset transistor M_{RST}. The source 254 of each reset transistor M_{RST} is operably coupled to a source supply voltage Vaa. Pixel array 250 may comprise an isolation region 256 configured to isolate pixel cells electrically and optically from one another to reduce dark current and cross-talk between adjacent pixels P1 and P2. A charge collected at photodiode PD may be transferred to the floating diffusion region FD by asserting the gate of transfer transistor M_{T}. Thereafter, as described above in reference to FIG. 2A, the charge on the floating diffusion region may be passed to a column line output 210 (see FIG. 2A). Conventional image sensor devices, as described above in reference to FIGS. 2A and 2B, may exhibit limitations due to the area constraints of the photodiode PD.

There is a need for methods, apparatuses. and systems to improve the quality of an imaging device. Specifically, there is a need for providing an image sensor device that exhibits the advantageous properties of conventional image sensor devices and FEDs while overcoming the aforementioned limitations.

### BRIEF DESCRIPTION OF THE DRAWINGS

In the drawings:

FIG. 1 is a cross-sectional view of a conventional field emission display including field emitter tips;

FIG. 2A is a circuit representation of a pixel within a conventional image sensor device;

FIG. 2A is a cross-sectional view of a portion of a pixel array within a conventional image sensor device;

FIG. 3 is an illustration of a field emitter image sensor device according to an embodiment of the invention;

FIGS. 4A illustrates a 4T (four-transistor) charge integrator in accordance with an embodiment of the invention;

FIGS. 4B illustrates a 3T (three-transistor) charge integrator in accordance with an embodiment of the invention;

FIG. 5 is a block diagram of a field emitter image sensor device including a pixel array with pixels in accordance with an embodiment of the invention; and

FIG. 6 is an illustration of a system including a field emitter image sensor device according to an embodiment of the invention.

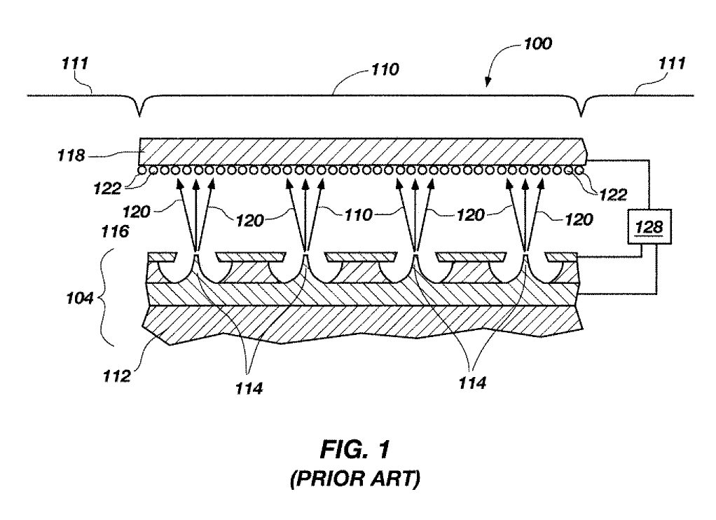

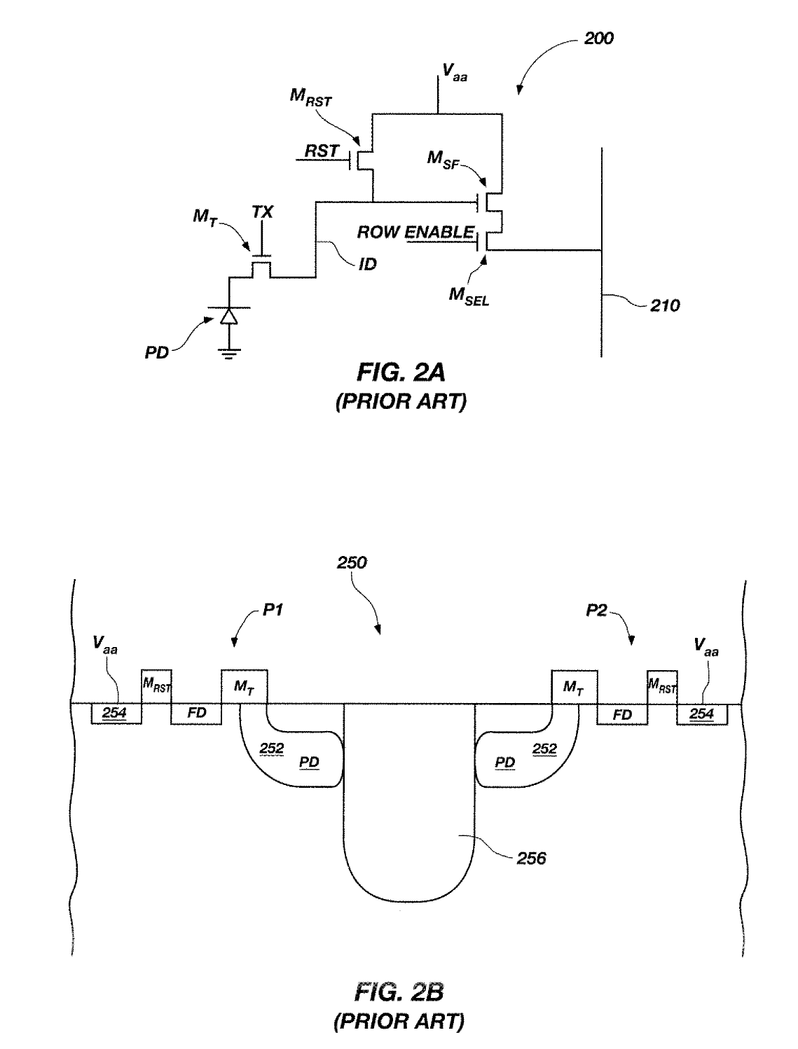

### DETAILED DESCRIPTION OF THE INVENTION

The present invention, in various embodiments, comprises methods, apparatuses, and systems for a field emitter image sensor device including a plurality of field emitter tips configured to emit electrons towards a plurality of anodes operably coupled to a pixel array.

In the following description, circuits and functions may be shown in block diagram form in order not to obscure the present invention in unnecessary detail. Conversely, specific circuit implementations shown and described are exemplary only and should not be construed as the only way to implement the present invention unless specified otherwise herein. Additionally, block definitions and partitioning of logic between various blocks is exemplary of a specific implementation. It will be readily apparent to one of ordinary skill in the art that the present invention may be practiced by numerous other partitioning solutions. For the most part. details concerning timing considerations and the like have been omitted where such details are not necessary to obtain a complete understanding of the present invention and are within the abilities of persons of ordinary skill in the relevant art.

In this description, some drawings may illustrate signals as a single signal for clarity of presentation and description. It will be understood by a person of ordinary skill in the art that the signal may represent a bus of signals, wherein the bus may have a variety of bit widths and the present invention may be implemented on any number of data signals including a single data signal.

The terms “assert” and “negate” are respectively used when referring to the rendering of a signal, status bit, or similar apparatus into its logically true or logically false state. If the logically true state is a logic level one, the logically false state will be a logic level zero. Conversely, if the logically true state is a logic level zero, the logically false state will be a logic level one.

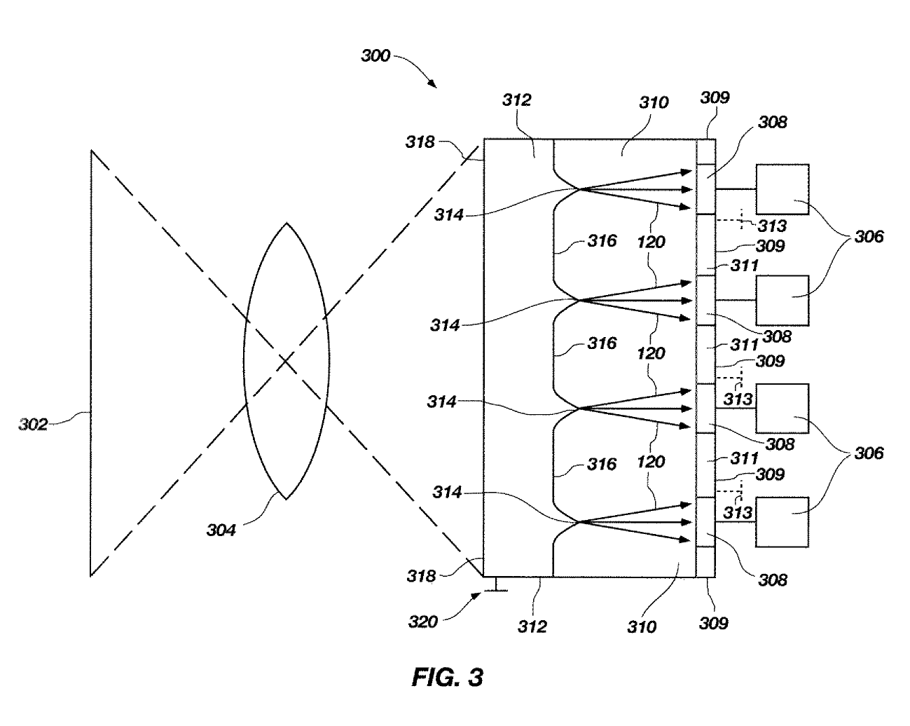

FIG. 3 illustrates a field emitter image sensor device 300 and an image 302 which is to be focused through lens 304 and onto field emitter image sensor device 300. Field emitter image sensor device 300 includes a first substrate 312 operably coupled to a reference voltage 320. For example only, reference voltage 320 may comprise a supply voltage or a ground voltage. By way of example, and not limitation, first substrate 312 may comprise an n-type doped silicon substrate. In another embodiment, first substrate 312 may comprise a p-type substrate operably coupled to ground voltage with an n-type doping surrounding each emitter tip. Substrate 312 may include a first surface 318 configured to sense light incident thereto and a second surface 316 including a plurality of emitter tips 314 configured to emit electrons 120 toward a plurality of anodes 308 configured to receive the electrons 120 and, thereafter, store the electron charges. For example only, and not by way of limitation, each emitter tip 314 may comprise an atomically sharp point for emitting electrons therethrough. Anodes 308 may be formed on a second substrate 309 and first substrate 312 and second substrate 309 may be hermetically sealed together. As a result, the plurality of field emitter tips 314 and the plurality of anodes 308 may be spaced apart from one another in a mutually parallel relationship with a vacuum space 310 therebetween. One or more field emitters 314 may emit electrons to one anode 308. In one embodiment, a metal layer 311 may be formed on substrate 309 between adjacent anodes 308. Metal layer 311 may be operably coupled to a positive supply voltage 313. As a result, metal layer 311 may attract stray electrons and, consequently, reduce crosstalk to adjacent anodes 308. For example only, and not by way of limitation, anodes 308 may comprise a conductive material such as, a polysilicon material, a copper/aluminum material, a copper material, or other metals. Each anode 308 may be operably coupled to a corresponding charge integrator 306 configured to, as described in more detail below, store and readout a charge located on the corresponding anode to a pixel array.

A contemplated operation of field emitter image sensor 300 will now be described. Initially, an image 302 may be focused through lens 304 and illuminated on the first surface 318 of first substrate 312. As incident light strikes the first surface 318, photons collide with and are absorbed by first substrate 312. As the photons are absorbed by first substrate 312, electron/hole pairs (not shown) are generated. The generated electrons 120 are released through emitter tips 314 and the holes are dissipated to ground voltage 320. The emitted electrons 120 are thereafter collected and stored on the corresponding anodes 308. As a result, the quantity of electrons collected and stored on each anode 308 is proportional to the quantity of photons striking the first surface 318 near the emitter tips 314 corresponding to that anode 308. As described below in greater detail, the charge on each anode 308 may be readout by a corresponding charge integrator 306.

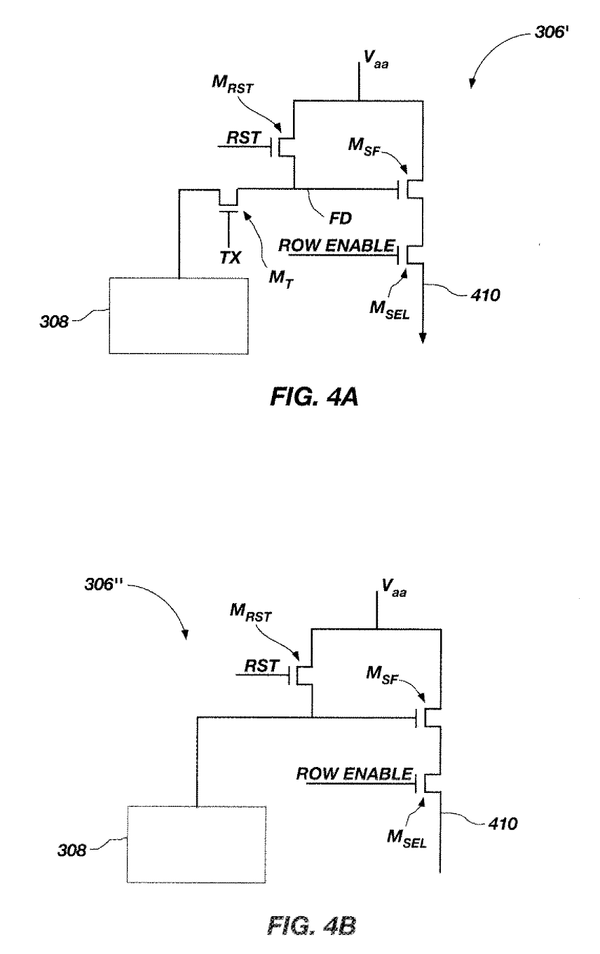

FIG. 4A illustrates an embodiment of the invention utilizing a four-transistor (4T) charge integrator 306 operably coupled to anode 308. Anode 308 may be operably coupled to a source of transfer transistor M_{T} configured for transferring a charge to an operably coupled floating diffusion region FD. A gate of transfer transistor M_{T} may be operably coupled to a transfer voltage TX which may be asserted to turn on transfer transistor M_{T} and allow a charge to be transferred from the anode 308 to the operably coupled floating diffusion region FD. Floating diffusion region FD is configured for passing a charge to a gate of an operably coupled source-follower transistor M_{SF}. In addition, floating diffusion region FD is operably coupled to a drain of a reset transistor M_{RST}, which is configured to reset the floating diffusion region FD to a predetermined voltage before a charge is transferred thereto from anode 308. A source of reset transistor M_{RST} may be operably coupled to supply voltage Vaa which may also be operably coupled to a source of source-follower transistor M_{SF}. Reset transistor M_{RST} may be controlled by a reset signal RST which may be asserted to turn on reset transistor M_{RST} and, as a result, reset the voltage at floating diffusion region FD to substantially near supply voltage Vaa. Source-follower transistor M_{SF} and row select transistor M_{SEL} may be operably coupled in series, source to drain, with the drain of row select transistor M_{SEL} operably coupled to a column line output 410. A gate of row select transistor M_{SEL} may be operably coupled to a row enable signal ROW ENABLE which may be asserted to turn on row select transistor M_{SEL}, and allow a current to flow through the source-follower transistor M_{SF} and row select transistor M_{SEL} and onto column line output 410, wherein the current is proportional to the voltage on the gate of source-follower transistor M_{SF}.

With a flow of electrons emitted from emitter tips 314 (see FIG. 3) and collected at anodes 308, the electron charges stored on anodes 308 may be read out by charge integrator 306′ in the following manner. Initially, TX and ROW ENABLE are negated and RST is asserted and, as a result, the charge at the floating diffusion region FD is at supply voltage Vaa. An image 302 (see FIG. 3) may then be captured by negating RST and asserting TX and, therefore, transferring the charge at anode 308 to floating diffusion region FD). Signal TX may then be negated and, subsequently the accumulated charge at the gate of source-follower transistor M_{SF} may be read out to column line output 410 by asserting ROW ENABLE. Subsequently, floating diffusion region FD may be reset to supply voltage Vaa by asserting RST. In one embodiment of the invention, the gates of transistors M_{RST}, M_{SEL} and M_{T} may include mask material formed thereover to prevent the transistors from collecting any electrons emitted from emitter tips 314 (see FIG. 3). By way of example only, and not by limitation, the gates of transistors M_{RST}, M_{SEL}, and M_{T} may include a mask material comprising a silicon oxide layer, a borophosphosilicate glass (BPSG) layer, or any other layer of known insulating material.

FIG. 4B illustrates an embodiment of he invention utilizing a three-transistor (3T) charge integrator 306″ operably coupled to an anode 308. In contrast to charge integrator 306′ illustrated in FIG. 4A, charge integrator 306″ does not include a transfer transistor. With a flow of electrons emitted from emitter tips 314 (see FIG. 3) and collected at anodes 308, the charges on anode 308 may be read out by charge integrator 306″ in the following manner. Initially, ROW ENABLE is negated and RST is asserted and, as a result, the charge at the gate of source-follower transistor M_{SF} is at supply voltage Vaa. An image 302 (see FIG. 3) may then be captured by negating RST and, therefore, allowing the charge at anode 308 to accumulate on floating diffusion region FD. While RST remains negated, the charge may be read out to column line 410 by asserting ROW ENABLE. Subsequently, ROW ENABLE may be negated and, thereafter, floating diffusion region FD may be reset to supply voltage Vaa by asserting RST. As described above, the gates of transistors M_{RST} and M_{SEL} may include a mask material formed thereover to prevent the transistors from collecting any electrons emitted from emitter tips 314 (see FIG. 3). By way of example only, and not by limitation, the gates of transistors M_{RST} and M_{SEL} may include a mask material comprising a silicon oxide layer, a borophosphosilicate glass (BPSG) layer, or any other layer of known insulating material,

Embodiments of a field emitter image sensor, as described above in reference to FIGS. 3, 4A, and 4B may comprise various advantages over the prior art. For example, illuminating a first surface of a substrate that comprises emitter tips on a second opposite surface may result in a superior quantum efficiency detector. Furthermore, collecting electron charges emitted from the emitted tips on the gate of a source-follower transistor will produce a sensitive photodetector, and outputting the electron charges to a pixel array will provide for a dense imager not constrained by the area of a photodiode.

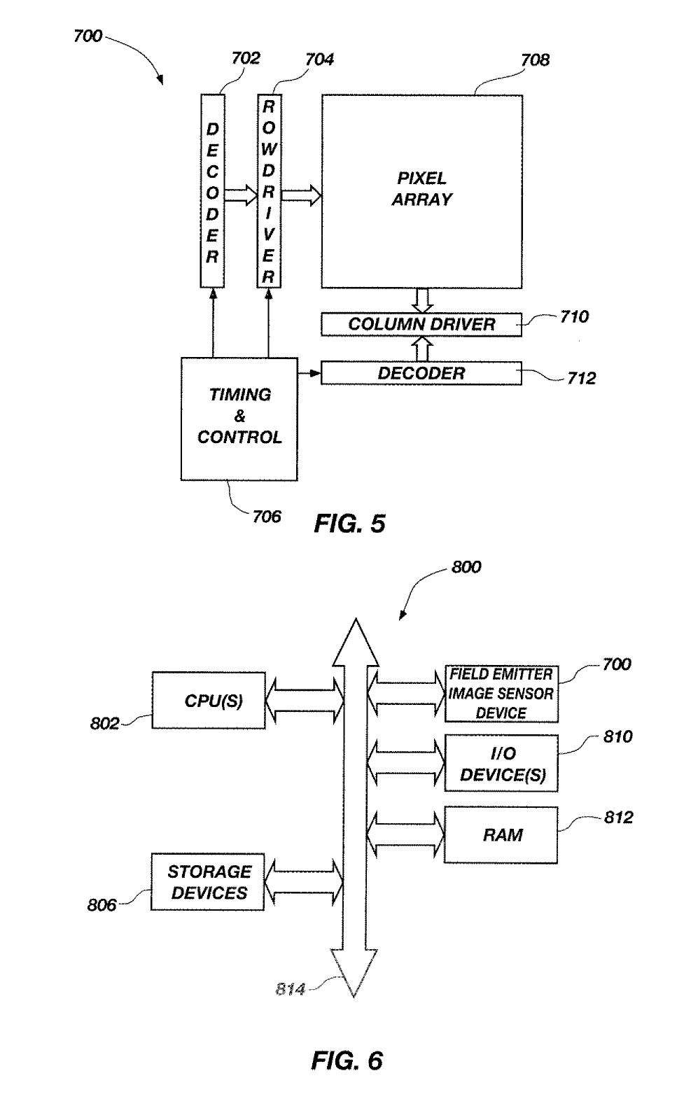

FIG. 5 is a block diagram for a field emitter image sensor device 700 having a pixel array 708 being constructed in accordance with an embodiment of the invention described above with reference to FIGS. 3, 4A, and 4B. Pixel array 708 comprises a plurality of pixels arranged in a predetermined number of columns and rows. The pixels of each row in array 708 are all turned on at the same time by a row select line and the pixels of each column are selectively output by a column select line. The row lines are selectively activated by the row driver 704 in response to row address decoder 702 and the column select lines are selectively activated by the column driver 710 in response to column address decoder 712. Therefore, a row and column address is provided for each pixel in pixel array 708. Field emitter image sensor device 700 is operated by the control circuit 706 which controls address decoders 702, 712 for selecting the appropriated row and column lines for pixel readout, and row and column driver circuitry 704, 710 which apply driving voltage to the drive transistors of the selected row ad column lines.

A processor based system 800 which includes a field emitter image sensor device 700 in accordance with an embodiment of the present invention is illustrated in FIG. 6. Without being limiting, such a system 800 may include a computer system, camera system, scanner, machine vision system, vehicle navigation system, video phone, surveillance system, auto focus system, star tracker system, motion detection system, image stabilization system, each of which may be configured to utilize an embodiment of the present invention.

A processor based system 800, such as a computer system, for example, generally comprises one or more central processing units (CPU) 802, for example, a microprocessor that may communicate with one or more input/output (I/O) devices 810 over a bus 814. The field emitter image sensor device 700 may also communicate with the system 800 over bus 814. The system 800 may also include random access memory (RAM) 812, and, in the case of a computer system, may include storage devices 806 which also communicate with CPU 802 over bus 814. Storage devices may include optical storage devices such as a compact disk (CD) ROM drives and digital versatile disk (DVD) ROM drives. Storage devices may also include electrical storage devices such as Flash memory and magnetic storage devices such as hard disk drives. Processor 802, field emitter image sensor device 700 and memory 812 may be integrated on a single IC chip.

Specific embodiments have been shown by way of non-limiting example in the drawings and have been described in detail herein; however, other embodiments may be susceptible to, and result from, various modifications and alternative forms to those disclosed. It should be understood that contemplated embodiments are not limited to the particular forms disclosed. Rather, the scope of the invention encompasses all modifications, variations, and alternatives as defined by the following appended claims and their legal equivalents.

What is claimed is:

1. A field emitter image sensor device, comprising:
a substrate having a first surface configured for sensing light incident thereto and a second surface opposite the first surface facing a plurality of anodes across a vacuum space; and
a plurality of emitter tips formed on the second surface of the substrate and configured to emit electrons toward the plurality of anodes, wherein each anode is configured to receive electrons from at least one emitter tip of the plurality.

2. The field emitter image sensor device of claim 1, further comprising a plurality of charge integrators configured to readout a charge, wherein each anode of the plurality is operably coupled to one charge integrator of the plurality.

3. The field emitter image sensor device of claim 2, wherein at least one charge integrator of the plurality comprises a 3T (three-transistor) charge integrator.

4. The field emitter image sensor device of claim 3, wherein a gate of a reset transistor and a gate of a row select transistor of the at least one 3T (three-transistor) charge integrator comprises a mask comprising an insulating material for isolating the reset transistor and row select transistor from emitted electrons.

5. The field emitter image sensor device of claim 2. wherein at least one charge integrator of the plurality comprises a 4T (four-transistor) charge integrator.

6. The field emitter image sensor device of claim 5, wherein a gate of a transfer transistor, a gate of a reset transistor. and a gate of a row select transistor of the at least one 4T (four-transistor) charge integrator comprises a mask comprising an insulating material for isolating the transfer transistor, the reset transistor, and the row select transistor from emitted electrons.

7. The field emitter image sensor device of claim 1, wherein each anode of the plurality comprises at least one of a copper/aluminum material a copper material, and a polysilicon material.

8. The field emitter image sensor device of claim 1, wherein each emitter tip of the plurality comprises an atomically sharp point.

9. The field emitter image sensor device of claim 1, wherein the substrate comprises an no type substrate operably coupled to a ground voltage.

10. An electronic system, comprising:
a processor-based device; and
a field emitter image sensor device operably coupled to the processor-based device and comprising:
a substrate having a first surface adapted for sensing light incident thereto and a second surface having a plurality of emitter tips formed thereon and adapted to emit electrons; and
a plurality of anodes located opposite the second surface across a vacuum space, wherein the plurality of anodes are adapted to receive emitted electrons.

11. The electronic system of claim 10, further comprising a plurality of charge integrators, each charge integrator operably coupled to one anode of the plurality and adapted to readout a charge.

12. The electronic system of claim 11, wherein each charge integrator of the plurality comprises a charge integrator selected from a group consisting of a 4T (four-transistor) charge integrator and a 3T (three-transistor) charge integrator.

13. The electronic system of claim 11, wherein each charge integrator comprises at least one transistor having a mask material comprising an insulating material adapted to isolate the at least one transistor from the emitted electrons.

14. The electronic system of claim 10, wherein each anode of the plurality comprises a material selected from the group consisting of a copper/aluminum material, a copper material. and a polysilicon material.

15. The electronic system of claim 10, wherein each emitter tip is configured to emit electrons through an atomically sharp point.

16. A method of operating a field emitter image sensor, comprising:
illuminating a first surface of a substrate with an image;
emitting electron charges from a plurality of emitter tips located on a second surface of the substrate, wherein the number of electrons emitted from each emitter tip is proportional to a number of photons striking the first surface substantially near the that emitter tip; and
collecting the emitted electrons at a plurality of anodes.

17. The method of claim 16, further comprising transferring electron charges from each anode to a charge integrator.

18. The method of claim 17, wherein transferring the electron charges to a charge integrator comprises transferring the electron charges to at least one 4T (four-transistor) charge integrator.

19. The method of claim 18, further comprising masking a gate of a reset transistor, a gate of a transfer transistor, and a gate of a row select transistor of the at least one 4T (four-transistor) charge integrator to isolate the reset transistor, the transfer transistor, and the row select transistor from the emitted electrons.

20. The method of claim 19, wherein masking the gate of the reset transistor, the gate of the transfer transistor, and the gate of the row select transistor comprises masking the gate of the reset transistor, the gate of the transfer transistor, and the gate of the row select transistor with an insulating layer.

21. The method of claim 17, wherein transferring the electron charges to a charge integrator comprises transferring the electron charges to at least one 3T (three-transistor) charge integrator.

22. The method of claim 21, further comprising masking a gate of a reset transistor and a gate of a row select transistor of the at least one 3T (three-transistor) charge integrator to isolate the reset transistor and the row select transistor from the emitted electrons.

23. The method of claim 22, wherein masking the gate of the reset transistor and the gate of the row select transistor comprises masking the gate of the reset transistor and the gate of the row select transistor with an insulating layer.

24. The method of claim 17, further comprising outputting the electron charges to a pixel array after transferring the electron charges to the charge integrator.

25. The method of claim 16, wherein illuminating a first surface of a substrate comprises illuminating a first surface of an n-type substrate operably coupled to a ground voltage.
